(19) United States
(12) Patent Application Publication
(10) Pub. No.: US 2014/0057435 A1
(43) Pub. Date: Feb. 27, 2014

(54) METHODS OF FORMING A METAL CAP LAYER ON COPPER-BASED CONDUCTIVE STRUCTURES ON AN INTEGRATED CIRCUIT DEVICE

(71) Applicants: Xunyuan Zhang, Albany, NY (US); Kunaljeet Tanwar, Slingerlands, NY (US); Ming He, Slingerlands, NY (US)

(72) Inventors: Xunyuan Zhang, Albany, NY (US); Kunaljeet Tanwar, Slingerlands, NY (US); Ming He, Slingerlands, NY (US)

(73) Assignee: GLOBALFOUNDRIES INC., Grand Cayman (KY)

(21) Appl. No.: 13/591,341

(22) Filed: Aug. 22, 2012

(51) Int. Cl. H01L 21/768

(52) U.S. Cl. 438/656; 438/652; 257/E21.585

(57) ABSTRACT

Disclosed herein are various methods of forming a metal cap layer on copper-based conductive structures on integrated circuit devices, and integrated circuit devices having such a structure. In one example, the method includes the steps of forming a conductive feature comprised of copper in a layer of insulating material, performing a metal removal process to remove a portion of the conductive feature and thereby define a recess above a residual portion of the copper feature, and performing a selective deposition process to form a cap layer comprised of cobalt, manganese, CoWP or NiWP within the recess.

### BACKGROUND OF THE INVENTION

1. Field of the Invention

Generally, the present disclosure relates to the manufacture of sophisticated semiconductor devices, and, more specifically, to various methods of forming a metal cap layer on copper-based conductive structures on integrated circuit devices and integrated circuit devices having such a structure.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Field effect transistors (NFET and PFET transistors) represent one important type of circuit element that substantially determines the performance capabilities of the integrated circuits. During the fabrication of complex integrated circuits using, for instance, MOS technology, millions of transistors, e.g., NFET transistors and/or PFET transistors, are formed on a substrate including a crystalline semiconductor layer. A basic field effect transistor comprises a source region, a drain region and a channel region extending between the source and drain regions. Such a transistor further includes a gate insulation layer positioned above the channel region and a gate electrode positioned above the gate insulation layer. When an appropriate voltage is applied to the gate electrode, i.e., a voltage that exceeds the threshold voltage of the transistor, the channel region becomes conductive and current may flow from the source region to the drain region. The gate electrode may be made of a variety of materials, e.g., polysilicon, one or more layers of metal or combinations thereof. The gate structure of the transistor may be made using so-called “gate-first” or “replacement gate” techniques. In one embodiment, the basic structure of a field effect transistor is typically formed by forming various layers of material and thereafter patterning those layers of material using known photolithography and etching processes. Various doped regions, e.g., source regions, drain regions, halo regions, etc., are typically formed by performing one or more ion implantation processes through a patterned mask layer using an appropriate dopant material, e.g., an N-type dopant or a P-type dopant, to implant the desired dopant material into the substrate. The particular dopant selected depends on the specific implant region being formed and the type of device under construction, i.e., an NFET transistor or a PFET transistor. During the fabrication of complex integrated circuits, millions of transistors, e.g., NFET transistors and/or PFET transistors, are formed on a substrate by performing a number of process operations.

However, the ongoing shrinkage of feature sizes on transistor devices causes certain problems that may at least partially offset the advantages that may be obtained by reduction of the device features. Generally, decreasing the size of, for instance, the channel length of a transistor typically results in higher drive current capabilities and enhanced switching speeds. Upon decreasing channel length, however, the pitch between adjacent transistors likewise decreases, thereby limiting the size of the conductive contact elements—e.g., those elements that provide electrical connection to the transistor, such as contact vias and the like—that may fit within the available real estate between adjacent transistors. Accordingly, the electrical resistance of conductive contact elements becomes a significant issue in the overall transistor design, since the cross-sectional area of these elements is correspondingly decreased. Moreover, the cross-sectional area of the contact vias, together with the characteristics of the materials they comprise, may have a significant influence on the effective electrical resistance and overall performance of these circuit elements.

Thus, improving the functionality and performance capability of various metallization systems has become important in designing modern semiconductor devices. One example of such improvements is the enhanced use of copper metallization systems in integrated circuit devices and the use of so-called “low-k” dielectric materials (materials having a dielectric constant less than 3) in such devices. Copper metallization systems exhibit improved electrical conductivity as compared to, for example, prior art metallization systems using aluminum for the conductive lines and vias. The use of low-k dielectric materials also tends to improve the signal-to-noise ratio (S/N ratio) by reducing crosstalk as compared to other dielectric materials with higher dielectric constants. However, the use of such low-k dielectric materials can be problematic as they tend to be less resistant to metal migration as compared to some other dielectric materials.

Copper is a material that is difficult to etch using traditional masking and etching techniques. Thus, conductive copper structures, e.g., conductive lines or vias, in modern integrated circuit devices are typically formed using known single or dual damascene techniques. In general, the damascene technique involves: (1) forming a trench/via in a layer of insulating material; (2) depositing one or more relatively thin barrier layers; (3) forming copper material across the substrate and in the trench/via; and (4) performing a chemical mechanical polishing process to remove the excess portions of the copper material and the barrier layer positioned outside of the trench/via to define the final conductive copper structure. The copper material is typically formed by performing an electrochemical copper deposition process after a thin conductive copper seed layer is deposited by physical vapor deposition on the barrier layer

FIGS. 1A-1C depict one illustrative example of a problem that may be encountered when conductive copper structures are formed on devices with very small features sizes and very small distances between adjacent devices. FIG. 1A depicts a portion of an integrated circuit product 100. More specifically, FIG. 1A depicts a portion of an illustrative metallization layer of the product 100. A typical integrated circuit product 100 will typically comprise multiple metallization layers, e.g., 10-14 metallization layers. In general, the metallization layers are comprised of layers of insulting material having various conductive metal lines and vias formed therein. In effect, the conductive structures in these various metallization layers constitute the “wiring” arrangement for the various elements of the electrical circuit, e.g., transistors, resistors, capacitors, etc., that are formed in a semiconducting substrate.

As shown in FIG. 1A, a plurality of conductive structures 12 are formed in an illustrative layer of insulating marital 10, e.g., a layer of silicon dioxide or a layer of so-called low-k insulating material (having a k value less than about 3.5). The composition of and methods of making the conductive structures 12 may vary depending upon the particular application. In one illustrative example, the conductive structure 12 is comprised of a bulk copper region 12A, an adhesion or liner layer 12B, such as tantalum or cobalt, and a so-called barrier layer 12C that may be comprised of a material such as tantalum nitride. The conductive structures 12 depicted in FIGS. 1A-1C are intended to be representative of any type of conductive structure that may be formed on integrated circuit products 100. The conductive structures 12 may be comprised of any of a variety of different materials and they may be formed using any of a variety of techniques. In one embodiment, the conductive structures 12 may be formed by defining the openings in the layer of insulating material 10, thereafter depositing the appropriate material layers in the openings and performing one or more chemical mechanical polishing (CMP) processes to remove the excess amounts of conductive material positioned outside of the openings defined in the layer of insulating material 10.

Next, as shown in FIG. 1B, a selective metal deposition process is performed to form metal cap layers 14 above each of the conductive structures 12. In one illustrative embodiment where the conductive structures 12 are comprised of bulk copper regions 12A, the selective deposition of the cap layer 14 may be formed by performing a selective chemical vapor deposition (CVD) process which exhibits deposition selectivity on copper over an interlayer dielectric, such as a selective cobalt or manganese CVD process. Other cap material may also be used, including CoWP or NiWP deposited via a selective CVD processes. The thickness of the cap layers 14 may vary depending on the particular application. For example, in one illustrative embodiment, the cap layers 14 may have a thickness of about 1-6 nm.

Then, as shown in FIG. 1C, a layer of insulating material 16, such as a silicon nitride material, is formed above the device 100 by performing, for example, a CVD process. In some embodiments, the layer of insulating material 16 may have a thickness of about 15-40 nm, depending upon the particular application. One problem associated with the process flow described above is that the cap layer 14 may have a lateral dimension 14D that is significantly greater than the lateral dimension 12D of the conductive contact 12. As a result of the excessively wide cap layer 14, the distance 18 between adjacent metal cap layers 14 becomes very small and may present some difficult issues for device manufacturers. For example, as the spacing 18 between adjacent cap layers 14 gets smaller, there is a greater tendency for break-down of the dielectric material, e.g., the silicon nitride layer material of the layer 16 that spans the distance 18. In a worst-case scenario, such a break-down may lead to complete device failure.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming a metal cap layer on copper-based conductive structures on integrated circuit devices, and integrated circuit devices having such a structure. In one example, the method includes the steps of forming a conductive feature comprised of copper in a layer of insulating material, performing a metal removal process to remove a portion of the conductive feature and thereby define a recess above a residual portion of the copper feature, and performing a selective deposition process to form a cap layer comprised of cobalt, manganese, CoWP or NiWP within the recess.

Another illustrative method disclosed herein includes forming a conductive feature comprised of copper in a layer of insulating material, performing a chemical mechanical polishing process to remove a portion of the conductive feature to thereby define a recess above a residual portion of the conductive feature, and performing a selective deposition process to form a cap layer comprised of cobalt, manganese, CoWP or NiWP within the recess on the residual portion of the conductive feature.

Yet another illustrative method disclosed herein includes forming a conductive feature comprised of copper in a layer of insulating material, performing a wet etching process to remove a portion of the conductive feature and thereby define a recess above a residual portion of the conductive feature, and performing a selective deposition process to form a cap layer comprised of cobalt, manganese, CoWP or NiWP within the recess on the residual portion of the conductive feature.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict one illustrative prior art process flow for forming metal cap layers on a conductive copper structure; and

FIGS. 2A-2D depict one illustrative novel process flow disclosed herein for forming conductive metal cap layers on conductive structures on an integrated circuit product.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming a metal cap layer on copper-based conductive structures on integrated circuit devices, and integrated circuit devices having such a structure. As will be readily apparent to those skilled in the art upon a complete reading of the present application, the present method is applicable to a variety of technologies, e.g., NFET, PFET, CMOS, etc., and is readily applicable to a variety of devices, including, but not limited to, ASIC's, logic devices, memory devices, etc. With reference to the attached drawings, various illustrative embodiments of the methods and devices disclosed herein will now be described in more detail.

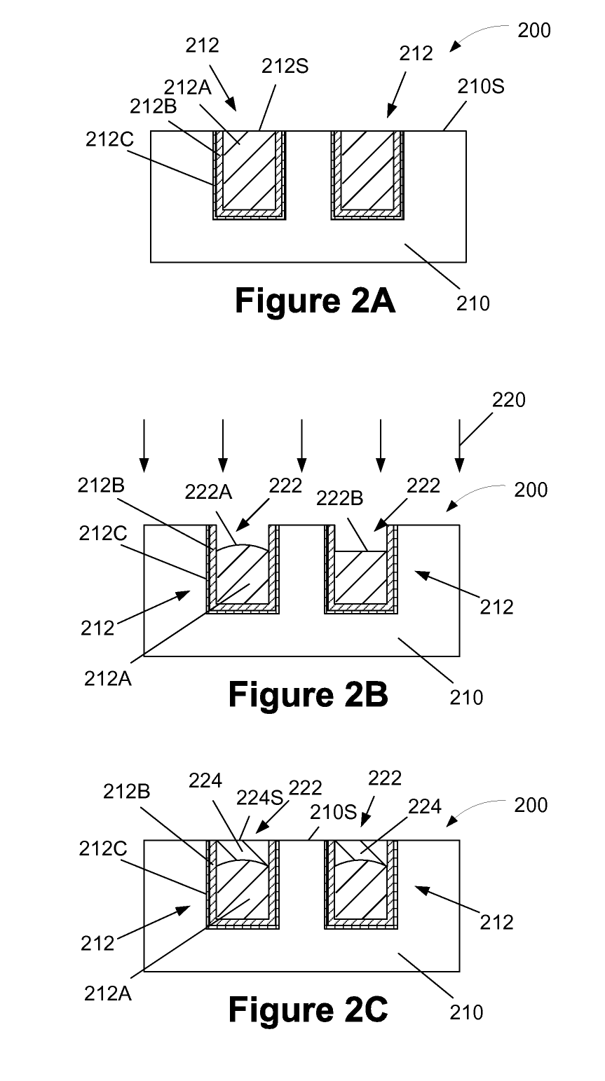

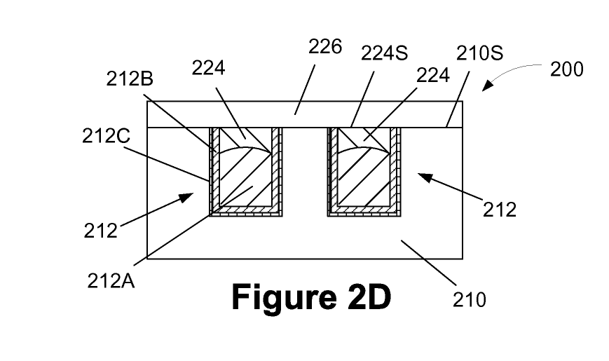

FIG. 2A-2D are simplified views of an illustrative integrated circuit device 200 at an early stage of manufacturing that is formed above a semiconducting substrate (not shown). The device 200 may be any type of integrated circuit device that employs any type of a conductive copper structure, such as a conductive line or via, commonly found on integrated circuit devices. At the point of fabrication depicted in FIG. 2A, a plurality of illustrative line/via conductive features 212 has been formed in the layer of insulating material 210 as part of a metallization layer of the device 200. In the example depicted in FIG. 2A, the upper surface 212S of the conductive feature 212 is substantially planar with the upper surface 210S of the layer of insulating material 210. However, the upper surface 212S may be a planar, concave or convex surface depending upon the CMP process employed and the liner material used. A typical integrated circuit product 200 will typically comprise multiple metallization layers, e.g., 10-14 metallization layers. In general, the metallization layers are comprised of layers of insulting material having various conductive metal lines and vias formed therein. In effect, the conductive structures in these various metallization layers constitute the “wiring” arrangement for the various elements (not shown) of the electrical circuit, e.g., transistors, resistors, capacitors, etc., that are formed in a semiconducting substrate. To facilitate disclosure of the present invention, only a single metallization layer will be depicted herein. However, after a complete reading of the present application, those skilled in the art will appreciate and understand that the inventions disclosed herein may be employed at any or all levels within an integrated circuit product.

The line/via conductive features 212 depicted in FIGS. 2A-2D are intended to be representative of any type of conductive copper structure that may be formed on an integrated circuit product. The illustrative line/via conductive features 212 may be of any desired shape, depth or configuration. For example, in some embodiments, the line/via conductive feature 212 may be a classic metal line that does not extend to an underlying layer of material (not shown). In other embodiments, the line/via conductive features 212 may be a through-hole type features, e.g., a classic via, that extends all of the way through the layer of insulating material 210 and contacts an underlying layer of material (not shown) or an underlying conductive structure (not shown). Thus, the shape, size, depth or configuration of the line/via conductive features 212 should not be considered to be a limitation of the present invention.

The layer of insulating material 210 is also intended to be representative in nature as it represents any type of insulating material, e.g., a layer of silicon dioxide or a layer of so-called low-k insulating material (having a k value less than about 3.5). The composition of and methods of making the conductive features 212 may vary depending upon the particular application. In one illustrative example, the conductive features 212 are comprised of a bulk copper region 212A, an adhesion or liner layer 212B, such as tantalum, ruthenium or cobalt, and a so-called barrier layer 212C that may be comprised of a material such as tantalum nitride. However, as noted above, the conductive features 212 may be comprised of any of a variety of different materials, they may have a variety of different configurations and they may be formed using any of a variety of techniques. In one embodiment, the conductive features 212 may be formed by defining the openings in the layer of insulating material 210, thereafter depositing the appropriate material layers in the openings and performing one or more chemical mechanical polishing (CMP) processes to remove the excess amounts of conductive material positioned outside of the openings defined in the layer of insulating material 210.

Next, as shown in FIG. 2B, a metal removal process 220 is performed on the device 200 to remove portions of the bulk copper material 212A and thereby define recesses 222 above the remaining portions of the bulk copper material 212A. In one illustrative embodiment, the metal removal process 220 may be a CMP process or an etching process.

In the case where the metal removal process 220 is a CMP process, it may result in the remaining portion of the bulk copper 212A having a convex surface 222A, as depicted for the conductive feature 212 shown on the left side of FIG. 2B. Depending upon the CMP process, the surface 222A may also be a substantially planar or concave surface. In the case where the metal removal process 220 is an etching process, the residual portion of the bulk copper 212A may have a substantially planar upper surface 222B, as depicted for the conductive feature 212 shown on the right side in FIG. 2B. The depth of the recesses 222 may vary depending upon the particular application. In one illustrative example, the recesses 222 may have a nominal depth that falls within the range of about 3-10 nm. For ease of reference, the upper surface of the residual portions of the conductive features 212 will hereinafter be depicted as having a curved upper surface 222A, although such a depiction should not be considered to be a limitation of the presently disclosed inventions.

In the case where the metal removal process is a CMP process, the CMP process may be performed using a selective slurry that allows for the effective removal of copper while remvoving little, if any, of the adjacent dielectric material. Such a selective slurry makes the CMP process primarily a chemical based process for removal of the copper material 212A with very little mechanical abrasion or erosion of the copper material 212A. The CMP process may also be a timed process so as to control the depth of the recesses 222. The parameters of the CMP process, and the slurry used in such a process, may vary depending upon the particular application. In one illustrative embodiment, the CMP process that is performed to define the recesses 222 may be a timed CMP process that is performed for about 45-60 seconds using an abrasive-less or colloidal silica as the slurry with hydrogen peroxide content ranging from 0.1-35.0% during the CMP process. The CMP process downforce pressure can range from about 0.1-3.0 psi.

In the case where the metal removal process 220 is a chemical etching process, it may be a timed wet etching process. For example, such a wet etching process may be performed for a duration of about 60-120 seconds using dilute hydrofluoric (HF) acid or SCl (ammonium, hydroxide, hydrogen peroxide, DIW) as the etchant material, and the etching process may be performed at a temperature that ranges from room temperature to about 200° C., depending upon the etch chemistry.

Next, as shown in FIG. 2C, a selective metal deposition process is performed to form metal cap layers 224 in the recesses 222 above each of the residual portions of the bulk copper material 212A. In the illustrative examples disclosed herein, the metal cap layers 224 may be comprised of cobalt, manganese, CoWP or NiWP. In one illustrative embodiment, the selective metal deposition process may be a selective atomic layer deposition (ALD) or a selective CVD process using cobalt carbonyl, cobalt amidinate, manganese carbonyl or manganese amidinate as precursor gases. In another example, the selective metal deposition process that is performed to form the cap layers 224 may be a selective CVD deposition process to form a material such as CoWP or NiWP, etc. In one embodiment, the selective metal deposition process may be timed such that the recesses 222 are substantially filled with the cap layers 224 when the selective metal deposition process is completed. In an alternative embodiment, the selective metal deposition process may be performed for a sufficient duration such that some of the cap layer overfills the recesses 222. In that case, one or more standard CMP processes may be performed to insure complete removal of excess copper material that is positioned outside of the recesses 222. In some cases, even when the selective metal deposition process is performed such that the metal cap layers 224 do not overfill the recesses 222, it still may be desirable to perform a brief standard CMP process to make sure that the upper surface of the layer of insulating material is free of residual copper material. In general, the metal cap layers 224 disclosed herein have an upper surface 224S that is substantially planar with the upper surface 210S of the layer of insulating material 210.

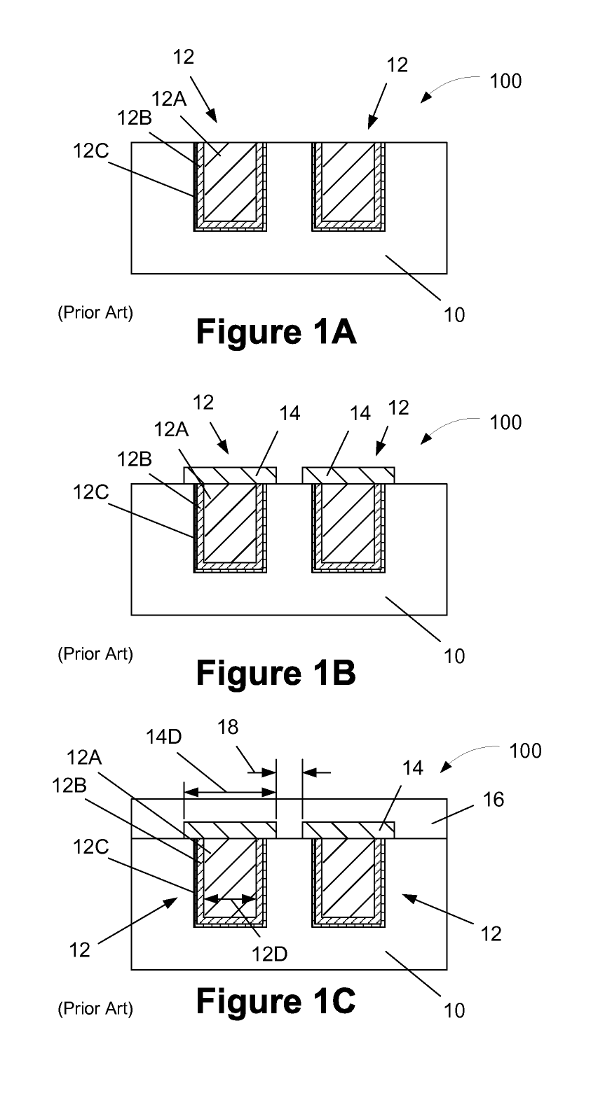

Then, as shown in FIG. 2D, a layer of insulating material 226, such as a silicon nitride material, is formed above the device 200 by performing, for example, a CVD process. In some embodiments, the layer of insulating material 226 may have a thickness of about 15-30 nm, depending upon the particular application. Using the novel process flow described herein may reduce the problem of excessive lateral growth of the cap layer 14 as described in the background section of this application. Reducing this excessive lateral growth of the metal cap layers may reduce the chance of undesirable breakdown of the insulation material between adjacent metal cap layers. Another benefit of the present invention is that, in the case where the layer of insulating material 210 has a lower k-value than that of the layer of insulating material 226, e.g., when the layer of insulating material 210 is a low-k material and the layer of insulating material 226 is silicon nitride, positioning of the cap layers 224 within the recesses 222, as described in FIGS. 2A-2D, effectively reduces the capacitance of the device as compared to the arrangement where the cap layers 14 were positioned above the layer of insulating material, as depicted in FIGS. 1A-1D.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a conductive feature comprised of copper in a layer of insulating material;
performing a metal removal process to remove a portion of said conductive feature and thereby define a recess above a residual portion of said copper feature; and
performing a selective deposition process to form a cap layer comprised of cobalt, manganese, CoWP or NiWP within said recess.

2. The method of claim 1, wherein forming said conductive feature comprises forming said conductive feature such that an upper surface of said conductive feature is substantially planar with an upper surface of said layer of insulating material.

3. The method of claim 1, wherein performing said metal removal process comprises performing a chemical mechanical polishing process to remove said portion of said conductive feature.

4. The method of claim 3, wherein, after performing said chemical mechanical polishing process, said residual portion of said copper surface has a convex upper surface.

5. The method of claim 3, wherein performing said chemical mechanical polishing process comprises performing said chemical mechanical polishing process using an abrasive-less or colloidal silica slurry with hydrogen peroxide content in range 0.1-35.0%.

6. The method of claim 1, wherein performing said metal removal process comprises performing a wet etching process to remove said portion of said conductive feature.

7. The method of claim 6, wherein performing said wet etching process comprises performing said wet etching process using one of dilute hydrofluoric (HF) acid or SCl as the etchant.

8. The method of claim 1, wherein performing said selective deposition process to form said cap layer comprised of cobalt, manganese, CoWP or NiWP within said recess comprises performing said selective deposition process to form said cap layer such that said cap layer has an upper surface that is substantially planar with said upper surface of said layer of insulating material.

9. The method of claim 1, wherein said layer of insulating material is comprised of silicon dioxide or an insulating material having a k value less than about 3.5.

10. The method of claim 1, wherein performing said selective deposition process to form said cap layer comprised of cobalt, manganese, CoWP or NiWP within said recess comprises performing a selective chemical vapor deposition process to form said cap layer.

11. The method of claim 10 wherein said selective chemical vapor deposition process is performed using precursor gases comprising cobalt carbonyl, cobalt amidinate, manganese carbonyl or manganese amidinate.

12. A method, comprising:
forming a conductive feature comprised of copper in a layer of insulating material;
performing a chemical mechanical polishing process to remove a portion of said conductive feature and thereby define a recess above a residual portion of said conductive feature, whereby an upper surface of said residual portion of said conductive feature is positioned below an upper surface of said layer of insulating material; and
performing a selective deposition process to form a cap layer comprised of cobalt, manganese, CoWP or NiWP within said recess on said residual portion of said conductive feature.

13. The method of claim 12, wherein forming said conductive feature comprises forming said conductive feature such that an upper surface of said conductive feature is substantially planar with an upper surface of said layer of insulating material.

14. The method of claim 12, wherein performing said chemical mechanical polishing process comprises performing said chemical mechanical polishing process using an abrasive-less or colloidal silica slurry with hydrogen peroxide content in range 0.1-35.0%.

15. The method of claim 12, wherein performing said selective deposition process to form said cap layer comprised of cobalt, manganese, CoWP or NiWP within said recess comprises performing said selective deposition process to form said cap layer such that said cap layer has an upper surface that is substantially planar with an upper surface of said layer of insulating material.

16. The method of claim 12, wherein performing said selective deposition process to form said cap layer comprised of cobalt, manganese, CoWP or NiWP within said recess comprises performing a selective chemical vapor deposition process to form said cap layer.

17. The method of claim 12, wherein said selective chemical vapor deposition process is performed using precursor gases comprising cobalt carbonyl, cobalt amidinate, manganese carbonyl or manganese amidinate.

18. A method, comprising:
forming a conductive feature comprised of copper in a layer of insulating material;
performing a wet etching process to remove a portion of said conductive feature and thereby define a recess above a residual portion of said conductive feature, wherein said residual portion of said conductive feature has a substantially planar surface that is positioned below an upper surface of said layer of insulating material; and
performing a selective deposition process to form a cap layer comprised of cobalt, manganese, CoWP or NiWP within said recess on said residual portion of said conductive feature.

19. The method of claim 18, wherein performing said wet etching process comprises performing said wet etching process using dilute hydrofluoric (HF) acid or SCl as the etchant material.

20. The method of claim 18, wherein performing said selective deposition process to form said cap layer comprised of cobalt, manganese, CoWP or NiWP within said recess comprises performing said selective deposition process to form said cap layer such that said cap layer has an upper surface that is substantially planar with said upper surface of said layer of insulating material.

21. The method of claim 18, wherein performing said selective deposition process to form said cap layer comprised of cobalt, manganese, CoWP or NiWP within said recess comprises performing a selective chemical vapor deposition process to form said cap layer.

22. The method of claim 18, wherein said selective chemical vapor deposition process is performed using precursor gases comprising cobalt carbonyl, cobalt amidinate, manganese carbonyl or manganese amidinate.
